(19) United States
(12) Patent Application Publication
(10) Pub. No.: US 2026/0012036 A1
(43) Pub. Date: Jan. 8, 2026

(54) ELECTRICAL INTERNAL GENERATOR

(71) Applicant: AF/GS EV IN-GEN Patent JV, Naperville, IL (US)

(72) Inventors: Ahmed Naveed Fazil, Prospect, IL (US); Glenn Seiden, Chicago, IL (US)

(21) Appl. No.: 19/325,276

(22) Filed: Sep. 10, 2025

Related U.S. Application Data
(63) Continuation-in-part of application No. 18/948,169, filed on Nov. 14, 2024.
(60) Provisional application No. 63/600,539, filed on Nov. 17, 2023.

(51) Int. Cl. H02J 9/06; F01P 5/02; F02D 35/00; H05K 7/20

(52) U.S. Cl. CPC H02J 9/061; F01P 5/02; F02D 35/00; H05K 7/209; H05K 7/20909

(57) ABSTRACT

An apparatus of the subject technology comprises a battery pack configured to provide power for a fixed structure and a motor powered by a fuel supplied by a fuel-delivery device and configured to provide mechanical power for one or more electrical machines. The one or more electrical machines are configured to generate a direct current (DC) voltage for charging the battery pack, and the battery pack, the motor and the one or more electrical machines are enclosed in a fixed system enclosure.

### CROSS-REFERENCE TO RELATED APPLICATIONS

This present application claims the benefit of priority under 35 U.S.C. 120 as a continuation-in-part of U.S. patent application Ser. No. 18/948,169, filed Nov. 14, 2024, which claims the benefit of U.S. Provisional Application No. 63/600,539, filed on Nov. 17, 2023, the disclosures of which are hereby incorporated by reference in their entirety for all purposes.

### TECHNICAL FIELD

The present disclosure generally relates to electric power generation, and more particularly, to electrical power generation for fixed structures.

### BACKGROUND

Modern cloud computing infrastructure, including data centers and server farms, demands a continuous and highly reliable power supply to ensure uninterrupted operation. In addition, commercial and industrial buildings also rely on stable power sources to support essential operations, including heating, ventilation and air conditioning (HVAC) systems, lighting, and security infrastructure. Traditional solutions for steady power generation in such environments typically involve a combination of grid electricity, uninterruptible power supplies (UPS), and backup diesel generators. These systems are designed to provide redundancy and failover capabilities, ensuring that even in the event of a grid failure, critical computing operations remain unaffected. However, these setups often require significant capital investment, ongoing maintenance, and complex integration with building management systems.

Among other limitations, UPS systems suffer from capacity limitations, as they are designed for short-term power supply (typically minutes), just enough to bridge the gap until a generator starts or to safely shut down systems. This makes application of UPS systems unsuitable for long-term or large-scale power needs. The same applies to backup diesel generators, which in addition, due to the types of fuel they use, can have environmental impacts by emitting greenhouse gases and particulate matter, contributing to air pollution and climate change.

### SUMMARY

According to some embodiments, an apparatus of the subject technology includes a battery pack configured to provide power for a fixed structure and a motor powered by a fuel supplied by a fuel-delivery device and configured to provide mechanical power for one or more electrical machines. The one or more electrical machines are configured to generate a direct current (DC) voltage for charging the battery pack, and the battery pack, the motor and the one or more electrical machines are enclosed in a fixed system enclosure.

According to other embodiments, a system consists of a fixed structure and an internal electrical generator system. The internal electrical generator system includes a battery pack to provide power for a fixed structure, a motor to be powered by a fuel and to provide mechanical power for one or more electrical machines, and a battery management system (BMS) to manage an operation of the motor. The battery system is enclosed in a fixed system enclosure.

According to yet other embodiments, a method includes providing a battery pack for supplying a first DC voltage to a fixed structure and electrically coupling the battery pack to an output of one or more electrical machines that generate a second DC voltage for charging the battery pack. The method further includes mechanically coupling an internal conversion engine (ICE) to the one or more electrical machines; and providing a fuel to the ICE.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments.

FIG. 1 is a high-level block diagram illustrating an example of a system of the subject technology.

FIG. 2 is a block diagram illustrating an example architecture of an internal generator system, according to some aspects of the subject technology.

FIG. 3 is a flow diagram illustrating an example of a method of providing an internal generator system for an EVIG, according to some aspects of the subject technology.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

In some aspects, the subject technology is directed to an internal generator for fixed structures including, but not limited to, data centers and server farms, businesses, industrial and residential buildings and other buildings. The internal generator of the subject technology consists of a battery system. The disclosed battery system includes a battery pack, an internal combustion engine (ICE), one or more electric machines (e.g., two) and a battery-management system (BMS) enclosed in a battery-system enclosure. The ICE provides mechanical power for the one or more electrical machines. The type and size of the ICE depends on the application and the space available. In some aspects, the ICE is powered by a fuel (e.g., a liquid fuel) supplied by a fuel source. In some implementations, the fuel may be provided by an external fuel source such as a fuel line (e.g., gas line) or other sources via a fuel pipe. The one or more electrical machines are configured to generate a DC voltage to keep the battery pack charged (e.g., fully charged). Examples of the electric machines include dynamos. The BMS is used to manage an operation of the ICE in some embodiments.

The battery pack provides electrical DC power for a fixed structure. The battery pack does not need to be plugged into an external charger such as a super charger or any other external charger. However, using an external charger may be an option when need arises, for example, when the ICE-based charging is not available due to a malfunction. The fuel provided through the fuel pipe can be the only source of power for the EV, but in general, the source of power is not limited to the fuel from the fuel pipe. The fuel can be a liquid fuel including, but not limited to, compressed natural gas (CNG), petrol, diesel, propane or hydrogen.

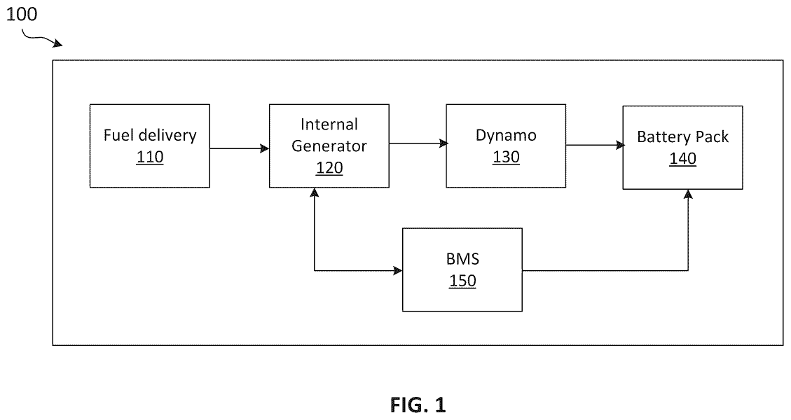

Turning now to the figures, FIG. 1 is a high-level block diagram illustrating an example of a system 100 of the subject technology. The system 100 includes a fuel-delivery device 110, an internal generator 120, dynamo 130, battery pack 140 and a BMS 150. The fuel delivery device 110 includes but is not limited to a fuel pipe that can be coupled to a fuel source (e.g., a gas line, a fuel tank, or a fuel truck), which can provide a fuel (e.g., containing stored chemical energy). In some aspects, the fuel consists of a liquid fuel, including but not limited to, CNG, petrol, diesel, propane or hydrogen. In some aspects, the internal generator 120 is a system enclosed in a battery-system enclosure that transforms the stored chemical energy into electrical energy and includes, but is not limited to, an ICE electrically coupled to the dynamo 130. In some aspects, the dynamo 130 may include one or more dynamos that provide electrical power for the battery pack 140. The dynamo 130 may also be referred to with a more general term such as an electric machine, which converts mechanical energy to electrical energy, especially DC electrical energy. In some aspects, the BMS 150 is an electronic control module such as a microcontroller or a field-programmable gate array (FPGA), which is in communication with the internal generator 120 and the battery pack 140. The BMS 150 is tasked to manage the operation of the internal generator 120 and proper charging of the battery pack 140, as described in more detail herein.

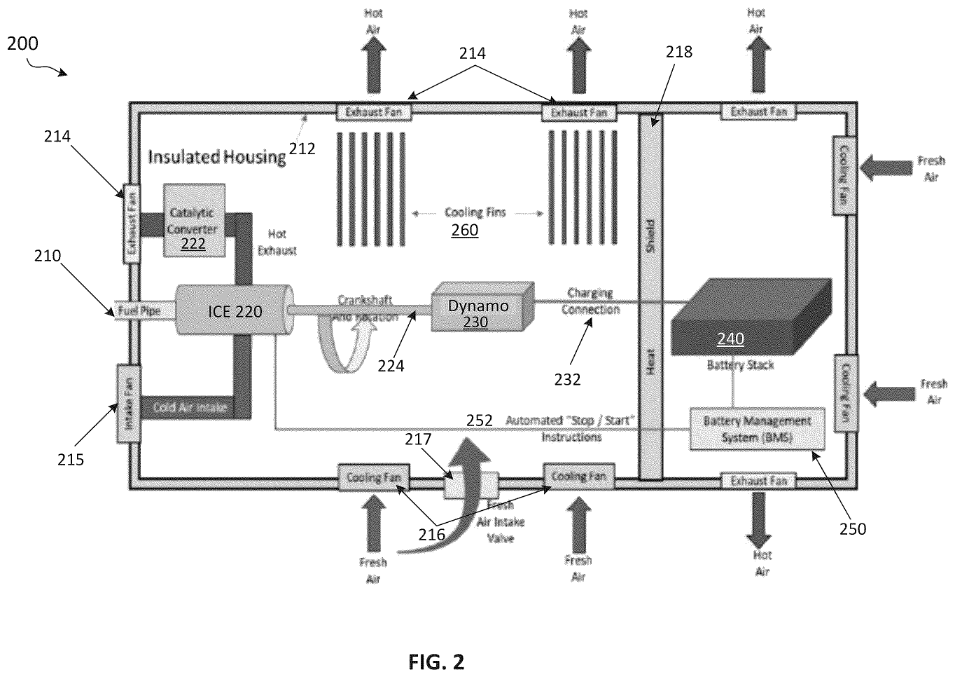

FIG. 2 is a block diagram illustrating an example architecture of an internal generator system 200, according to some aspects of the subject technology. In some implementations, the internal generator system 200 can include a fuel pipe 210 for connection to a fuel source, an ICE 220, a dynamo 230, a battery pack (stack) 240, a BMS 250, cooling fins 260, all or partially enclosed in an insulated housing 212 (also referred to as the battery system enclosure). The insulated housing 212 has two compartments separated by a heat shield 218 that isolates the battery pack 240 and the BMS 250 from the rest of the components. In some implementations, not shown in FIG. 2, the BMS 250 may be installed outside of the compartment including the battery pack 240. The insulated housing 212 further includes exhaust fans 214, an intake fan 215, cooling fans 216 and a fresh-air intake valve 217. The intake fan 215 blows in cold air to cool the ICE 220. The host exhaust from the ICE 220 may be passed through a catalytic converter 222 before being blown out via the exhaust fan 214. Other exhaust fans 214 blow out the hot air from the cooling fins 260, the battery pack 240 and the BMS 250. The cooling fans 216 blow in fresh air from the outside environment to help cool the components inside the insulated housing 212.

The ICE 220 is powered by a suitable fuel, from a list including, but not limited to, CNG, petrol, diesel, propane or hydrogen, through the fuel pipe 210 from a fuel source (e.g., a gas line, a fuel tank, or a fuel truck). The dynamo 230 is mechanically coupled to the ICE 220 by a crankshaft 224, which causes rotation of an armature of the dynamo 230 to generate a DC voltage for charging the battery pack 240 though the charging connection (e.g., copper wires) 232. The BMS 250 is an electronic control module such as a microcontroller or an FPGA that can be programmed to control operation of the ICE 220 to maintain the battery pack charge, for example, fully charged (e.g., within 98% to 100% of maximum charging capacity of the battery pack). For example, the BMS 250 can send stop/start instructions 252 to the ICE 220 to control start and stop of the ICE 220. In some implementations, the BMS 250 may also control the operations of the exhaust fans 214, the intake fan 215 and the cooling fans 216. In some implementations, the BMS 250 may capture data in real-time and/or near-real-time and forward the captured data to the ICE 220, the battery pack 240 or an external source.

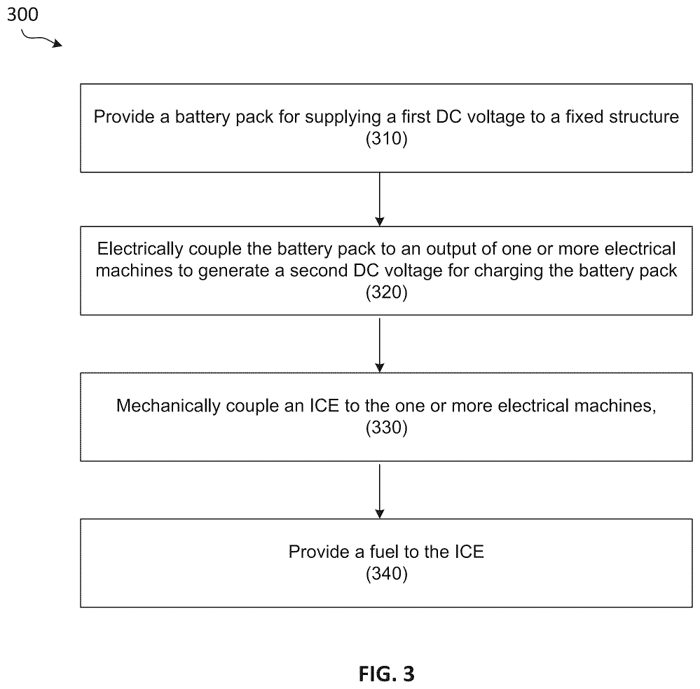

FIG. 3 is a flow diagram illustrating an example of a method 300 of providing an IG system (e.g., 100 of FIG. 1) according to some aspects of the subject technology. The method 300 includes steps 310, 320, 330 and 340.

In step 310, a battery pack (e.g., 140 of FIG. 1 or 240 of FIG. 2) for supplying a first DC voltage to a fixed structure (e.g., a data center and a server farm, a business, industrial or residential building) is provided.

In step 320, the battery pack is electrically coupled to an output of one or more electrical machines (e.g., 130 of FIG. 1 or 230 of FIG. 2) that generate a second DC voltage for charging the battery pack.

In step 330, an ICE (e.g., 110 of FIG. 1 or 220 of FIG. 2) is mechanically coupled to the one or more electrical machines.

In step 340, a fuel is provided to the ICE through a fuel pipe (e.g., 210 of FIG. 2). The fuel may consist of a liquid fuel including, but not limited to, CNG, petrol, diesel, propane or hydrogen.

An aspect of the subject technology is directed to an apparatus including a battery pack that provides power for a fixed structure and a motor, powered by a fuel supplied by a fuel-delivery device, to provide mechanical power for one or more electrical machines. The one or more electrical machines generate a DC voltage for charging the battery pack, and the battery pack, the motor and the one or more electrical machines are enclosed in a fixed system enclosure.

In some implementations, the motor comprises an ICE including a multiple-stroke ICE.

In one or more implementations, the one or more electric machines comprise one or more dynamos, wherein the DC voltage is regulated to match a nominal voltage of the battery pack.

In some implementations, the fuel comprises one of compressed natural gas (CNG), petrol, diesel, propane or hydrogen.

In one or more implementations, the battery pack can be fully charged, for example, within a range of about 98 to 100 percent of a maximum allowable charge level associated with the battery pack.

In some implementations, the fuel is the fuel supplied by a fuel-delivery device including a fuel pipe.

In one or more implementations, a fixed system enclosure further includes an internal heat shield arranged to shield a battery compartment including the battery pack from other components in the fixed system enclosure.

In some implementations, the fixed system enclosure further includes a battery-management system (BMS) in communication with the motor and the battery pack.

In some implementations, the BMS is configured to control an operation of the motor to keep the battery pack charged at a desired level.

In one or more implementations, the fixed system enclosure further includes cooling fins made of a heat conductive material.

In some implementations, the fixed system enclosure further includes a plurality of exhaust fans configured to remove hot air from compartments of the fixed system enclosure.

In one or more implementations, the fixed system enclosure further includes a plurality of cooling fans configured to blow fresh air into compartments of the fixed system enclosure.

Another aspect of the subject technology is directed to a system consisting of a fixed structure and an internal electrical generator system. The internal electrical generator system includes a battery pack to provide power for a fixed structure, a motor to be powered by a fuel and to provide mechanical power for one or more electrical machines, and a BMS to manage an operation of the motor. The battery system is enclosed in a fixed system enclosure.

In some implementations, the BMS is configured to manage an operation of the motor to charge the battery pack at a desired level.

In one or more implementations, the motor comprises an ICE, wherein the one or more electric machines comprise one or more dynamos.

In some implementations, the fuel includes one of CNG, petrol, diesel, propane or hydrogen provided through a fuel-delivery device including a fuel pipe.

In one or more implementations, the fixed system enclosure further includes cooling fins made of a heat conductive material.

In some implementations, the fixed system enclosure further includes a number of exhaust fans to remove hot air from compartments of the fixed system enclosure and a couple of cooling fans to blow fresh air into the compartments of the fixed system enclosure.

Yet another aspect of the subject technology is directed to a method including providing a battery pack for supplying a first DC voltage to a fixed structure and electrically coupling the battery pack to an output of one or more electrical machines that generate a second DC voltage for charging the battery pack. The method further includes mechanically coupling an ICE to the one or more electrical machines; and providing a fuel to the ICE.

In one or more implementations, the battery pack, the ICE, and the one or more electrical machines are enclosed in a fixed system enclosure, wherein the fixed system enclosure further includes cooling fins, a plurality of exhaust fans and a plurality of cooling fans.

In some implementations, the method further comprises providing a BMS to manage an operation of the ICE to keep the battery pack charged at a desired level.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

Aspects of the subject matter described in this disclosure can be implemented to realize one or more of the following potential advantages. The described techniques may be implemented to support a range of benefits and significant advantages of the disclosed eye tracking system. It should be noted that the subject technology enables fabrication of a depth-sensing apparatus that is a fully solid-state device with small size, low power, and low cost.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. An apparatus, comprising:
a battery pack configured to provide power for a fixed structure; and
a motor powered by a fuel and configured to provide mechanical power for one or more electrical machines,
wherein:
the one or more electrical machines are configured to generate a direct current (DC) voltage for charging the battery pack; and
the battery pack, the motor and the one or more electrical machines are enclosed in a fixed system enclosure.

2. The apparatus of claim 1, wherein the motor comprises an internal combustion engine (ICE).

3. The apparatus of claim 1, wherein the one or more electric machines comprise one or more dynamos, and wherein the DC voltage is regulated to match a nominal voltage of the battery pack.

4. The apparatus of claim 1, wherein the fuel comprises one of compressed natural gas (CNG), petrol, diesel, propane or hydrogen.

5. The apparatus of claim 1, wherein the charged battery pack comprises a fully charged battery pack that is charged to a level within a range of about 98 to 100 percent of a maximum allowable charge level associated with the battery pack.

6. The apparatus of claim 1, wherein the fuel is supplied by a fuel-delivery device including a fuel pipe.

7. The apparatus of claim 1, wherein the fixed system enclosure further includes an internal heat shield arranged to shield a battery compartment including the battery pack from other components in the fixed system enclosure.

8. The apparatus of claim 1, wherein the fixed system enclosure further includes a battery-management system (BMS) in communication with the motor and the battery pack.

9. The apparatus of claim 8, wherein the BMS is configured to control an operation of the motor to keep the battery pack charged at a desired level.

10. The apparatus of claim 1, wherein the fixed system enclosure further includes cooling fins made of a heat conductive material.

11. The apparatus of claim 1, wherein the fixed system enclosure further includes a plurality of exhaust fans configured to remove hot air from compartments of the fixed system enclosure.

12. The apparatus of claim 1, wherein the fixed system enclosure further includes a plurality of cooling fans configured to blow fresh air into compartments of the fixed system enclosure.

13. A system, comprising:
a fixed structure; and
an internal electrical generator system comprising:
a battery pack configured to provide power for a fixed structure;
a motor configured to be powered by a fuel and to provide mechanical power for one or more electrical machines, wherein the one or more electrical machines are configured to generate a DC voltage for charging the battery pack; and
a BMS configured to manage an operation of the motor,
wherein the internal electrical generator system is enclosed in a fixed system enclosure.

14. The system of claim 13, wherein the BMS is configured to manage an operation of the motor to charge the battery pack at a desired level.

15. The system of claim 13, wherein the motor comprises an ICE, and wherein the one or more electric machines comprise one or more dynamos.

16. The system of claim 13, wherein the fuel includes one of CNG, petrol, diesel, propane or hydrogen provided through a fuel-delivery device including a fuel pipe.

17. The system of claim 13, wherein the fixed system enclosure further includes:
cooling fins made of a heat conductive material;
a plurality of exhaust fans configured to remove hot air from compartments of the fixed system enclosure; and
a plurality of cooling fans configured to blow fresh air into the compartments of the fixed system enclosure.

18. A method, comprising:
providing a battery pack for supplying a first DC voltage to a fixed structure;
electrically coupling the battery pack to an output of one or more electrical machines to generate a second DC voltage for charging the battery pack;
mechanically coupling an ICE to the one or more electrical machines; and
providing a fuel to the ICE.

19. The method of claim 18, wherein the battery pack, the ICE, and the one or more electrical machines are enclosed in a fixed system enclosure, wherein the fixed system enclosure further includes cooling fins, a plurality of exhaust fans and a plurality of cooling fans.

20. The method of claim 19, further comprising providing a BMS to manage an operation of the ICE to keep the battery pack charged at a desired level.
